(19) United States
(12) Patent Application Publication
(10) Pub. No.: US 2012/0286385 A1
(43) Pub. Date: Nov. 15, 2012

(54) SEMICONDUCTOR DEVICE, CAMERA MODULE, AND SEMICONDUCTOR DEVICE MANUFACTURING METHOD

(75) Inventor: Shigeru Yamada, Tokyo (JP)

(73) Assignee: LAPIS SEMICONDUCTOR CO., LTD., Tokyo (JP)

(21) Appl. No.: 13/555,259

(22) Filed: Jul. 23, 2012

Related U.S. Application Data
(62) Division of application No. 12/372,770, filed on Feb. 18, 2009.

(30) Foreign Application Priority Data
Mar. 7, 2008 (JP) 2008-058283

(51) Int. Cl. H01L 31/0203; H01L 31/0232

(52) U.S. Cl. 257/432; 257/433; 257/E31.117; 257/E31.127

(57) ABSTRACT

A semiconductor device is provided which has a semiconductor element having an element forming surface at which a sensor element is formed, a back surface on the opposite side of the element forming surface, and a light transmissive protective member laminated over the element forming surface via an adhering portion. The semiconductor device includes a region exposed from the protective member at the outer peripheral end portion of the semiconductor element, when viewed from the protecting member in a laminating direction.

### CROSS-REFERENCE TO RELATED APPLICATION

This application is a divisional application of application Ser. No. 12/372,770 filed on Feb. 18, 2009, which claims priority under 35 USC 119 from Japanese Patent Application No. 2008-058283, the disclosure of which is incorporated by reference herein.

### BACKGROUND OF THE INVENTION

1. Field of the Invention

The invention relates to a semiconductor device, a camera module, and a semiconductor device manufacturing method. More specifically, the invention relates to a semiconductor device which has a protecting member over an element forming surface of a semiconductor element, a camera module, and a semiconductor device manufacturing method.

2. Description of Related Art

A solid-state image sensing device (semiconductor element) such as a CCD sensor is a package formed in such a manner that a wire formed on the element is protected by a glass sheet. The solid-state image sensing device is inserted into a holder into which a lens is incorporated, and is used as a camera module. If position shifting on the transmitting path of an incident light is caused between the lens and the wire, the light receiving position of the incident light is shifted. An accurate signal may not be obtained.

There has been proposed a configuration in which the holder is contacted with the surface of the protecting glass sheet formed over the semiconductor element so as to adjust the horizontal plane of the lens and the element forming surface of the semiconductor element (see Japanese Patent Application Laid-Open (JP-A) No. 2003-332545 and Japanese Patent National Publication No. 2005-533452).

As illustrated in FIG. 17, in such camera module, the correcting of parallelism of a holder 807 is performed via an adhering portion 802 and a protecting glass sheet (protecting member) 801 on a semiconductor element 803. That is, the correcting of parallelism of the holder 807 is performed on a contacting surface 808 of the holder 807 and the protecting glass sheet 801, i.e., the holder 807 and the semiconductor element 803 become parallel. The distance z between a lens 806 and an element forming surface 805 is varied by the variation of the film thickness of the adhering portion 802 and the variation of the sheet thickness of the protecting glass sheet 801. An accurate signal may not be obtained. Fine adjustment is necessary. The protecting glass sheet 801 typically has a tolerance of 10%. The sheet thickness of the protecting glass sheet 801 is 0.3 to about 0.5 mm. Therefore, the protecting glass sheet 801 has a variation of .+−.30 to 50 .mu.m. The film thickness of the adhering portion 802 also has about the same variation. To reduce the variation, the protecting glass sheet polished at high accuracy is used. The variation of the distance z between the lens 806 and the element forming surface 805 may be slightly reduced. However, the cost may be increased.

### SUMMARY OF THE INVENTION

The invention has been made in view of the above problems and an object of the invention is to achieve the following object.

An object of the invention is to provide a semiconductor device which may reduce the distance between a lens and an element forming surface, a camera module, and a semiconductor device manufacturing method.

As a result of earnest studying, the inventors have found that the above problems may be addressed using the following semiconductor device and have achieved the above object.

That is, a first aspect of the present invention provides a semiconductor device including:
a semiconductor element having an element forming surface at which a sensor element is formed, and a back surface at an opposite side of the element forming surface; and
a light transmissive protective member laminated over the element forming surface via an adhering portion, wherein
when viewed from a side of the protective member in a laminating direction, the semiconductor device is provided with a region exposed from the protective member at an outer peripheral end portion of the semiconductor element.

Further, a second aspect of the present invention provides a camera module including a lens, a holder in which the lens is inserted and which holds the lens therein, and a semiconductor device in which a protective member is laminated via an adhering portion over an element forming surface at which a semiconductor element sensor is formed,
wherein the semiconductor device is the semiconductor device of claim 1 and the holder is fixed so as to engage an exposed region of the semiconductor device.

In addition, a third aspect of the present invention provides a semiconductor device manufacturing method including:
preparing a semiconductor wafer having, on its front surface, a plurality of semiconductor element regions, each including a sensor element forming region at which a sensor element is formed;
forming an adhering portion on the plurality of semiconductor element regions;
laminating a light transmissive protective member over the semiconductor wafer via the adhering portion;
dicing a portion of the protective member corresponding to an outer peripheral end portion along a first direction of outer peripheral end portions of the semiconductor element region at a first width along the first direction to expose a portion of the semiconductor element region; and
dicing the portion of the exposed semiconductor element region at a second width that is smaller than the first width.

The semiconductor device manufacturing method may further include:
dicing a portion of the protective member corresponding to the outer peripheral end portion along a second direction perpendicular to the first direction of the outer peripheral end portions of the semiconductor element region at a third width along the second direction to expose a portion of the semiconductor element region; and
dicing the portion of the exposed semiconductor element region at a fourth width that is smaller than the third width.

In the semiconductor device manufacturing method of the third aspect of the present invention, the first width and the third width may have the same width.

The semiconductor device manufacturing method may further include:
dicing an outer peripheral end portion along a second direction perpendicular to the first direction of the outer peripheral end portions of the semiconductor element region and dicing the protective member corresponding to the outer peripheral end portion along the second direction.

According to the invention, there may be provided the semiconductor device which may maintain the distance between the lens and the element forming surface constant, the camera module, and the semiconductor device manufacturing method.

### BRIEF DESCRIPTION OF THE DRAWINGS

FIG. 1 is a cross-sectional view of a semiconductor device according to an exemplary embodiment of the invention;

FIG. 2A is a schematic sectional view of the semiconductor device according to an exemplary embodiment of the invention;

FIG. 2B is an enlarged view of a vicinity region of a correcting-of-position surface in FIG. 2A;

FIG. 3A is a perspective plan view of the semiconductor device according to an exemplary embodiment of the invention, seen from a protecting member in a laminating direction;

FIG. 3B is a perspective plan view of the semiconductor device according to an exemplary embodiment of the invention, seen from a protecting member in a laminating direction;

FIG. 4A is a perspective plan view of a semiconductor device according to an exemplary embodiment of the invention, seen from a protecting member in a laminating direction;

FIG. 4B is a perspective plan view of a semiconductor device according to an exemplary embodiment of the invention, seen from a protecting member in a laminating direction;

FIG. 4C is a perspective plan view of a semiconductor device according to an exemplary embodiment of the invention, seen from a protecting member in a laminating direction;

FIG. 4D is a perspective plan view of a semiconductor device according to an exemplary embodiment of the invention, seen from a protecting member in a laminating direction;

FIG. 5 is a cross-sectional view of a camera module according to an exemplary embodiment of the invention;

FIG. 6A is a schematic sectional view of the camera module according to an exemplary embodiment of the invention;

FIG. 6B is an enlarged view of a vicinity region of a correcting-of-position surface in FIG. 6A;

FIG. 7 is a perspective plan view of the camera module according to an exemplary embodiment of the invention, seen from a protecting member in a laminating direction;

FIG. 8 is a perspective plan view of a camera module according to an exemplary embodiment of the invention, seen from a protecting member in a laminating direction;

FIG. 9 is a cross-sectional view of a camera module according to an exemplary embodiment of the invention;

FIG. 10 is a cross-sectional view of a camera module according to an exemplary embodiment of the invention;

FIGS. 11A to 11E are process sectional views of the semiconductor device according to an exemplary embodiment of the invention;

FIGS. 12F to 12J are process sectional views of the semiconductor device according to an exemplary embodiment of the invention;

FIGS. 13H to 13J are process plan views of FIGS. 12H to 12J according to an exemplary embodiment of the invention;

FIG. 14 is a process plan view for manufacturing the semiconductor device illustrated in FIG. 3B according to an exemplary embodiment of the invention;

FIG. 15 is a process plan view for manufacturing the semiconductor device illustrated in FIG. 3B according to an exemplary embodiment of the invention;

FIGS. 16H to 16J are process plan views for manufacturing the semiconductor device illustrated in FIG. 4A according to an exemplary embodiment of the invention; and

FIG. 17 is a cross-sectional view of a conventional camera module.

### DETAILED DESCRIPTION OF THE INVENTION

Exemplary embodiments of the invention will be described below with reference to the drawings. The drawings schematically illustrate the shape, size, and arrangement relation of components to the extent that the invention may be understood. It should be noted that the invention is not limited to these. In the following description, specific materials and conditions and numerical conditions may be used, which is only one of preferred examples. It should be noted that the invention is not limited to these.

### <Semiconductor Device>

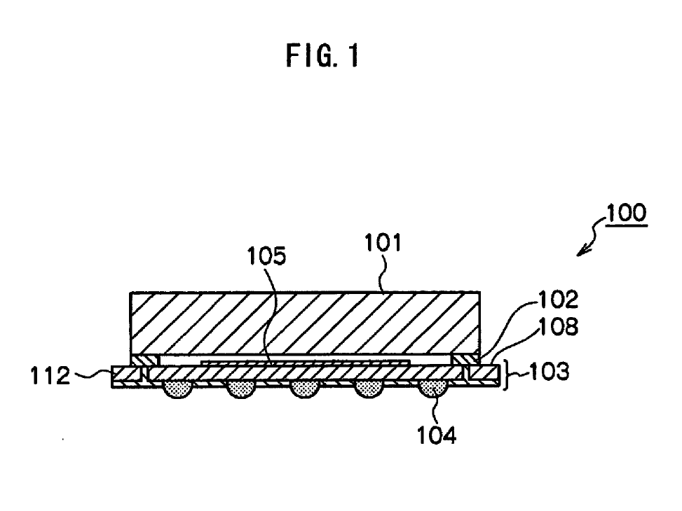

FIG. 1 is a cross-sectional view of a semiconductor device 100 of the present invention. The semiconductor device 100 includes a semiconductor element 103 which has an element forming surface at which a sensor element 105 is formed, and a back surface on the opposite side of the element forming surface; and a light transmissive protective member 101 laminated over the element forming surface via an adhering portion 102.

Further, when viewed from a side of the protective member in a laminating direction, the semiconductor device 100 has an exposed region 108 at the outer peripheral end portion of the semiconductor element 103. The exposed region (hereinafter, called a “correcting-of-position surface”, as needed) 108 is provided for the correcting of parallelism of a holder of a later-described camera module. The holder is mounted on the exposed region 108 to improve the accuracy of the distance between a lens and the element forming surface.

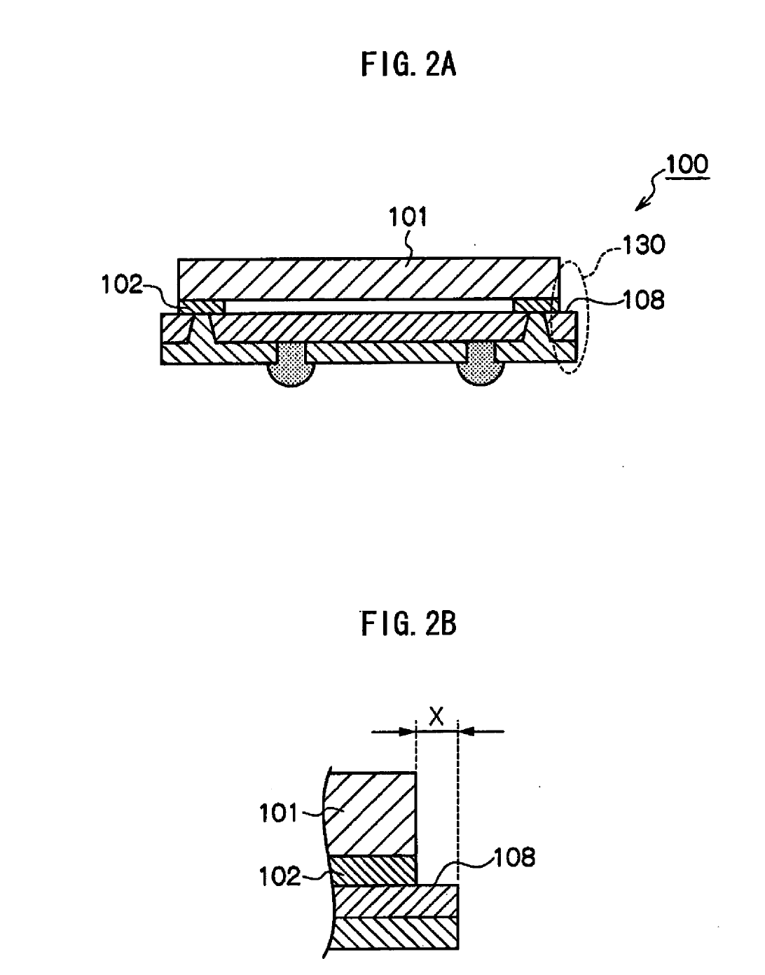

FIG. 2A is a schematic sectional view of the semiconductor device 100 of the present invention. FIG. 2B is an enlarged view of a vicinity region 130 of the correcting-of-position surface 108 in FIG. 2A. In FIG. 2B, a width x of the correcting-of-position surface 108 is not limited to the configuration shown in FIGS. 2A and 2B, if the later-described holder may be stably mounted. However, from the viewpoint of the processing accuracy of the holder, it is preferred that the width x is from 20 μm to 100 μm. When the width x is less than 20 μm, a region on which the holder is mounted becomes too small so that the holder and the correcting-of-position surface 108 cannot be engaged. When the width x is greater than 100 μm, the outer shape size of the semiconductor device 100 is increased, which goes against the requirement for reduction in size.

In the invention, it is preferred that the correcting-of-position surface 108 is provided along each of at least one pair of opposing sides at the outer peripheral ends of the semiconductor element.

In a method of providing the correcting-of-position surface 108, a component used as the correcting-of-position surface 108 may be prepared so as to be separately provided at the outer peripheral end of the semiconductor element 103. Otherwise, the area of the semiconductor element 103 may be larger than that of the protecting member 101 to expose the outer peripheral end of the semiconductor element 103. In the case of separately providing the correcting-of-position surface 108, the process for separately providing the correcting-of-position surface 108 at the outer peripheral end of the semiconductor element 103 is necessary. This results in that the size accuracy and increase in size and the number of processes of the semiconductor device are necessary. Therefore, to reduce the size and the number of processes of the semiconductor device, it is preferred that the area of the semiconductor element 103 is larger than that of the protecting member 101 to expose the outer peripheral end of the semiconductor element 103.

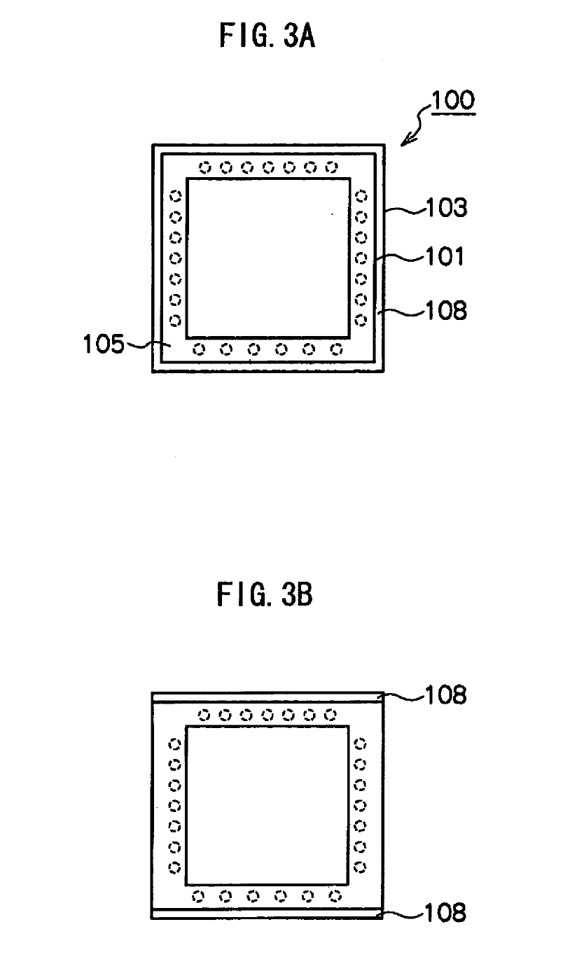

FIG. 3A is a perspective plan view of the semiconductor device 100 having the correcting-of-position surface 108, seen from the protecting member 101 in a laminating direction. As illustrated in FIG. 3A, the correcting-of-position surface 108 is arranged so as to surround the protecting member 101 in a laminating direction. The correcting-of-position surface 108 may stably engage the holder.

The contacting area of the correcting-of-position surface 108 and the holder need to be reduced to easily process the holder. As illustrated in FIG. 3B, it is preferred that at least one pair of opposing sides at the outer peripheral ends of the semiconductor element 103 be exposed. Since the contacting area of the correcting-of-position surface 108 and the holder mounted thereon is reduced, the correcting of parallelism of the holder may be easily performed. It is preferred in that the correcting-of-position surface is formed by dicing only the two opposing sides.

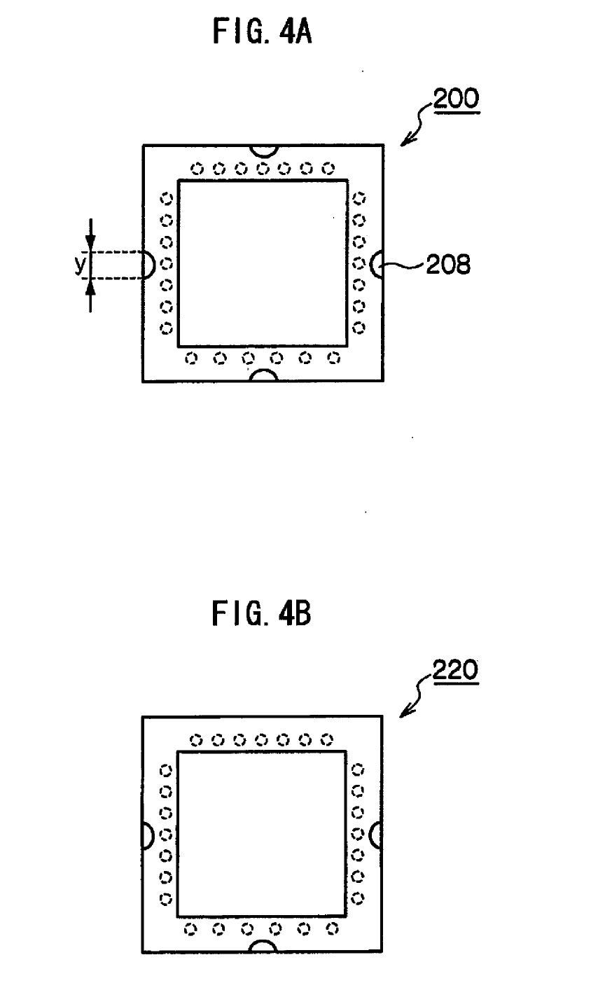

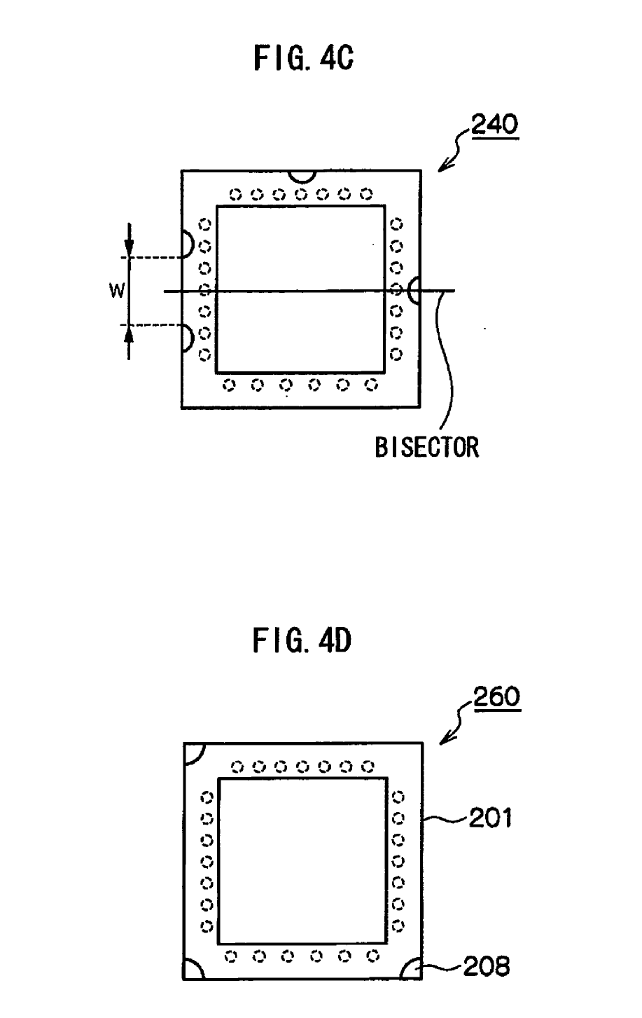

The contacting area of the correcting-of-position surface 108 and the holder need to be reduced. More preferably, a correcting-of-position surface 208 is provided partially (on a portion of a side) at the outer peripheral end of the semiconductor element. As illustrated in FIG. 4A, more preferably, the correcting-of-position surface 208 is provided in the center portion of each of at least a pair of opposing sides at the outer peripheral ends of the semiconductor element. As illustrated in FIG. 4C, here, the center portion represents a position where the correcting-of-position surface 208 intersects or is contacted with a line which bisects the opposing sides of the outer peripheral ends. The shape of the correcting-of-position surface 208 may be selected according to the position where the correcting-of-position surface 208 is provided, as needed. As illustrated in FIG. 4A, the shape of the correcting-of-position surface 208 may be semicircular. When the correcting-of-position surface 208 is located at the corner portion of the semiconductor element, as illustrated in FIG. 4D, the shape of the correcting-of-position surface 208 may be fan-shaped or triangular.

As illustrated in FIG. 4B, more preferably, at least one correcting-of-position surface is provided on each of a pair of opposing sides of the semiconductor element and at least three correcting-of-position surfaces are provided at the outer peripheral ends of the semiconductor element 103. The correcting-of-position surface is provided in such position to minimize the dicing of a protecting member 201. Since three or more correcting-of-position surfaces 208 are provided, the holder may be stably supported. Therefore, the distance between the lens and the element forming surface may be maintained constant. Specifically, as illustrated in FIG. 4B, the three correcting-of-position surfaces 208 are provided in the opposite positions with reference to the center portion of the semiconductor element. At least one of the correcting-of-position surfaces 208 is located on a side intersecting the opposing sides.

As illustrated in FIG. 4C, particularly preferably, two correcting-of-position surfaces are provided on one side in positions symmetrical with the line which bisects the opposing sides and one correcting-of-position surface is provided on the other side on the line which bisects the opposing sides. In this case, the distance W of the two correcting-of-position surfaces 208 provided on one side need to be at least a width y (y in FIG. 4A) of the correcting-of-position surface 208 or more. When the W is smaller than the width y, the holder is supported by the two correcting-of-position surfaces. Therefore, the correcting-of-position surface 208 may not stably engage the holder.

Most preferably, the correcting-of-position surface is provided at the corner portion of the semiconductor element. As illustrated in FIG. 4D, the correcting-of-position surfaces 208 are provided at three corners. In this case, the contacting area of the correcting-of-position surface 208 and the holder may be reduced. In addition, since the corners of the protecting member 201 are processed, From the viewpoint of the processability, the correcting-of-position surface 208 may be easily formed. Here, the term “corner portion” represents a portion for providing the correcting-of-position surface 208 and a region so as not to be contacted with the adhering portion.

The semiconductor device of the invention may be used for the camera module, a fingerprint sensor, an illumination sensor, and an ultraviolet sensor. In particular, the semiconductor device of the invention is useful as the camera module.

An exemplary embodiment of the camera module will be described below in detail.

### <Camera Module>

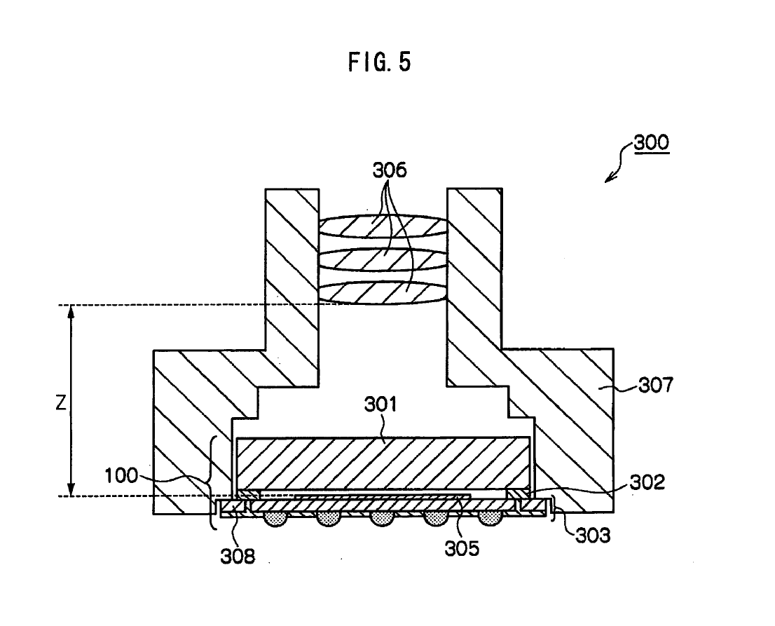

FIG. 5 is a cross-sectional view of a camera module 300 of the invention. The camera module 300 of the invention has a lens 306, a holder 307 which inserts and holds the lens 306 therein, and a semiconductor device in which a protecting member 301 is laminated via an adhering portion 302 over an element forming surface formed with a sensor element 305 of a semiconductor element 303. The semiconductor device has the above configuration in which the holder 307 is fixed so as to engage a correcting-of-position surface 308 of the semiconductor device.

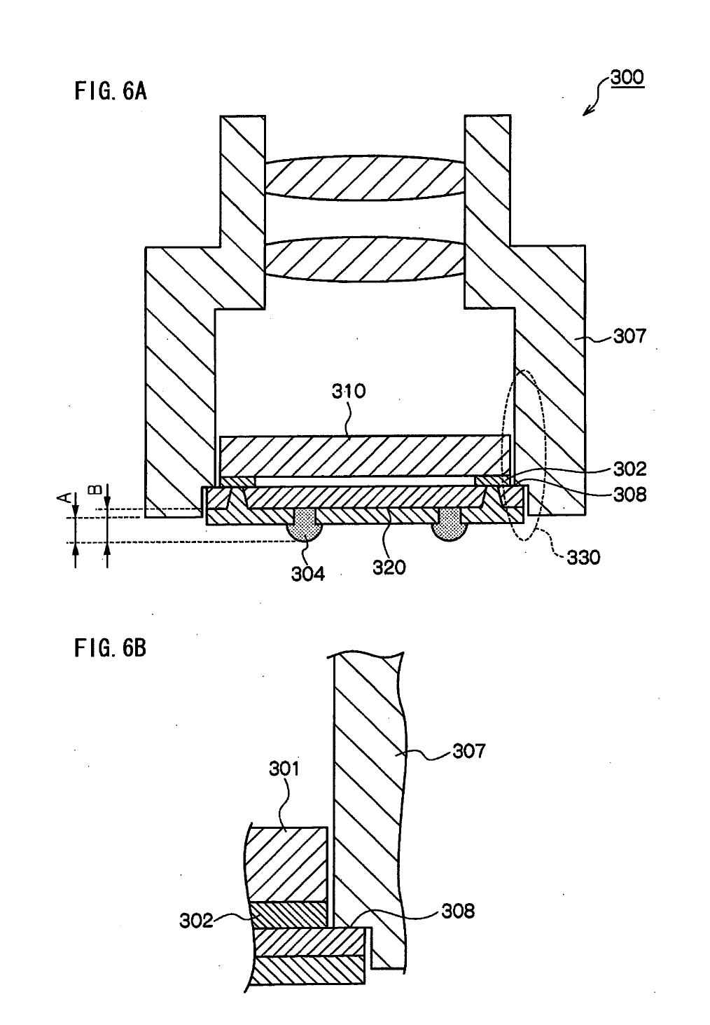

FIG. 6A is a schematic sectional view of the camera module 300 of the invention. FIG. 6B is an enlarged view of a vicinity region 330 of the correcting-of-position surface 308 in FIG. 6A. In FIG. 6B, the holder 307 is fixed so as to engage the correcting-of-position surface 308. The holder 307 may be positioned by the correcting-of-position surface 308 of the semiconductor element 303. The distance between the lens 306 and the element forming surface 305 may be maintained constant.

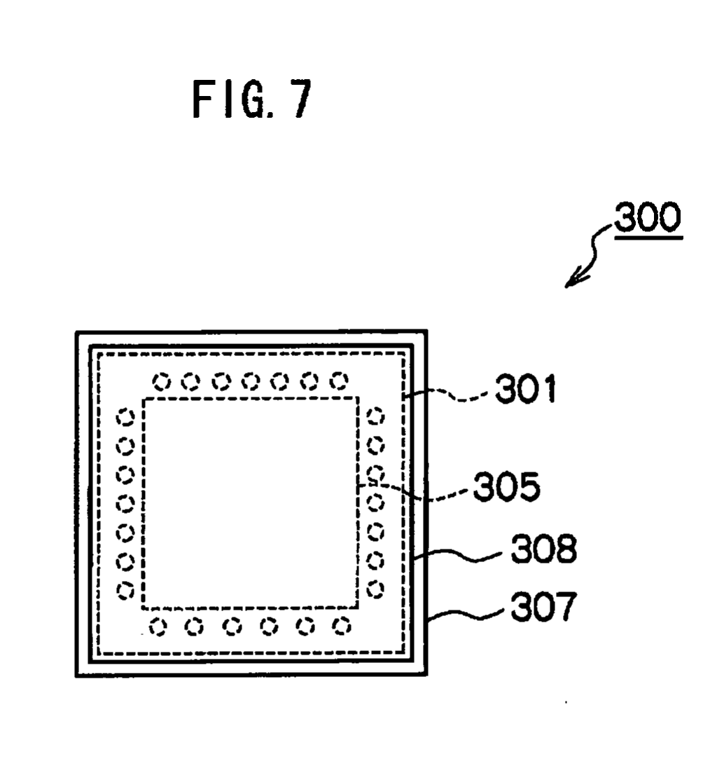

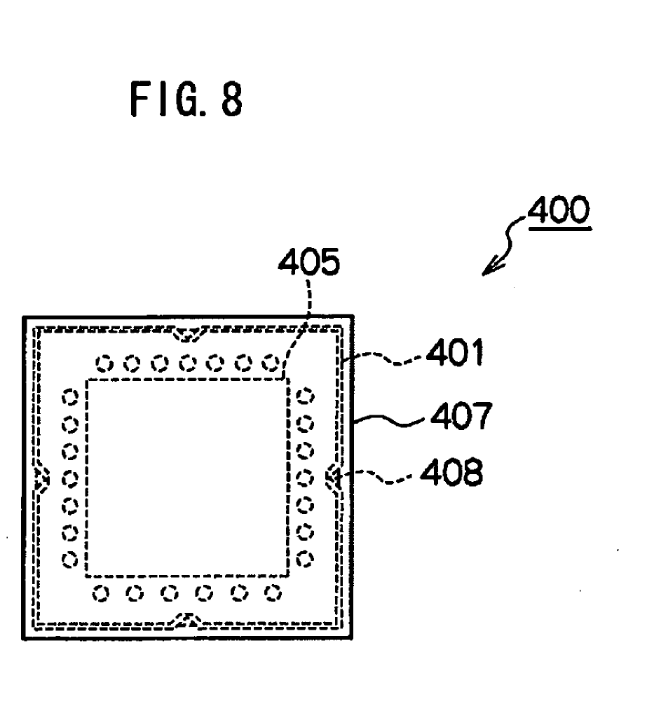

FIG. 7 is a perspective plan view of the camera module 300 of the invention, seen from the protecting member 301 in a laminating direction. Specifically, FIG. 7 is a diagram in which the holder 307 is mounted on the semiconductor device 100 illustrated in FIG. 3. FIG. 8 is a diagram in which the correcting-of-position surface is changed from a semicircular shape to a trapezoidal shape in a semiconductor device 200 illustrated in FIG. 4A and a holder 407 whose surface opposite a correcting-of-position surface 408 is triangular is mounted. The inner peripheral portion of the holder needs to be formed in a shape having a surface which may be mounted on the correcting-of-position surface of the semiconductor device.

### [Engaging Means of the Semiconductor Device and the Holder]

The engaging means of the semiconductor device and the holder of the invention, after the holder is mounted on the semiconductor device, may be a means for fixing the contacting portion by resin or a means for pressing and fixing the semiconductor device by a jig such as a screw or a spring provided on the holder 307. When the semiconductor device is fixed by the jig, the semiconductor device and the holder may be assembled over and over again. Therefore, the accuracy of the distance between the lens and the element forming surface may be improved. The number of failures of the camera module may be reduced. The engaging means of the semiconductor device and the holder is preferred.

### [Holder]

The holder of the invention is a member for inserting and holding the lens therein and maintaining the distance between the element forming surface over the semiconductor device and the lens constant.

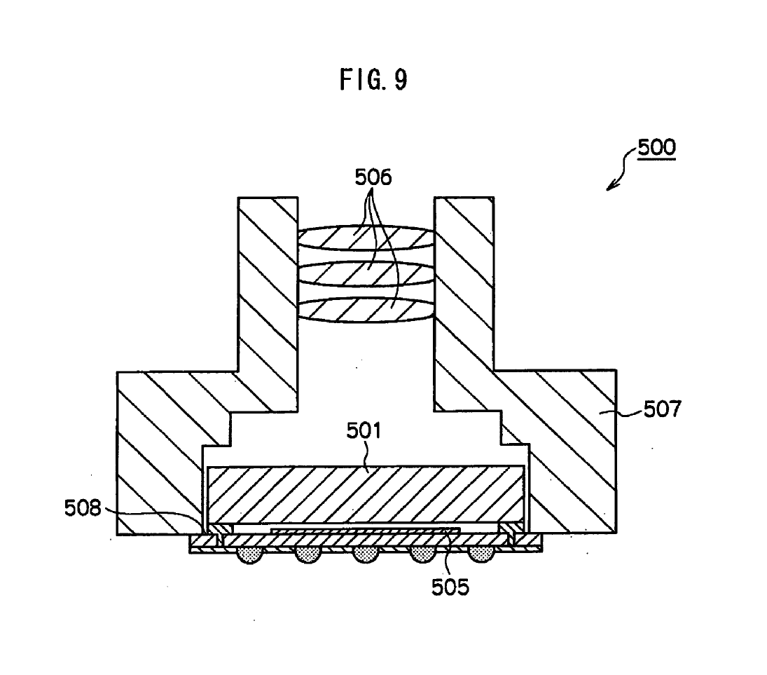

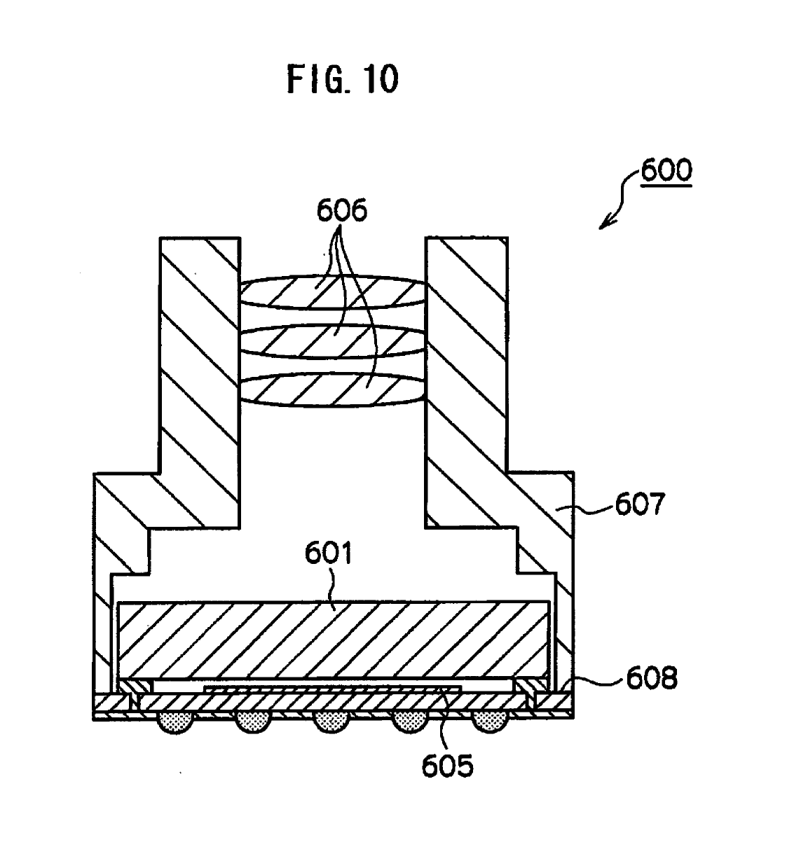

To easily process the inner surface of the holder, as illustrated in FIG. 9, it is preferred that the holder 507 mounted on the correcting-of-position surface 508 of the semiconductor element has a shape which is flush with a correcting-of-position surface 508. More preferably, as illustrated in FIG. 10, to make the camera module smaller, a holder 607 has a shape in which the width of the holder 607 coincides with the width of the semiconductor element.

As illustrated in FIG. 5, to reliably shield the incidence of light from the side portion on the semiconductor element, it is preferred that the holder has a shape which completely covers the side portion of the semiconductor element 303. Specifically, as illustrated in FIG. 6A, it is preferred that the distance A between the surface of the holder 307 on the side of an external terminal 304 and the external terminal 304 is shorter than the distance B from the surface of a semiconductor wafer 320 on the side of the external terminal 304 to the external terminal 304. In the case of a CMOS sensor or a CCD sensor, an image may be deteriorated due to the incidence of light from the side surface. Therefore, the distance A between the surface of the holder 307 on the side of the external terminal 304 and the external terminal 304 need to be larger than 0. That is, in FIG. 6A, the surface of the holder 307 on the side of the external terminal 304 needs to be higher than the external terminal 304. The connection failure of the external terminal 304 and an external circuit may be prevented. In addition, the tilting of the camera module due to the contact of the substrate formed with the external circuit and the holder may be prevented.

<A Semiconductor Device Manufacturing Method>

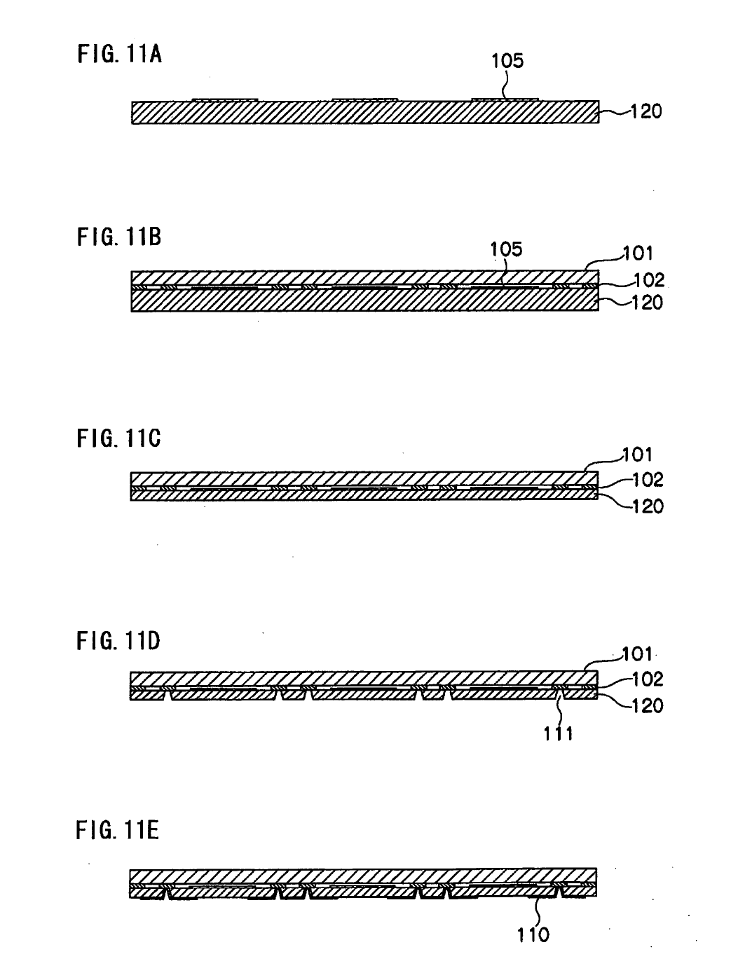

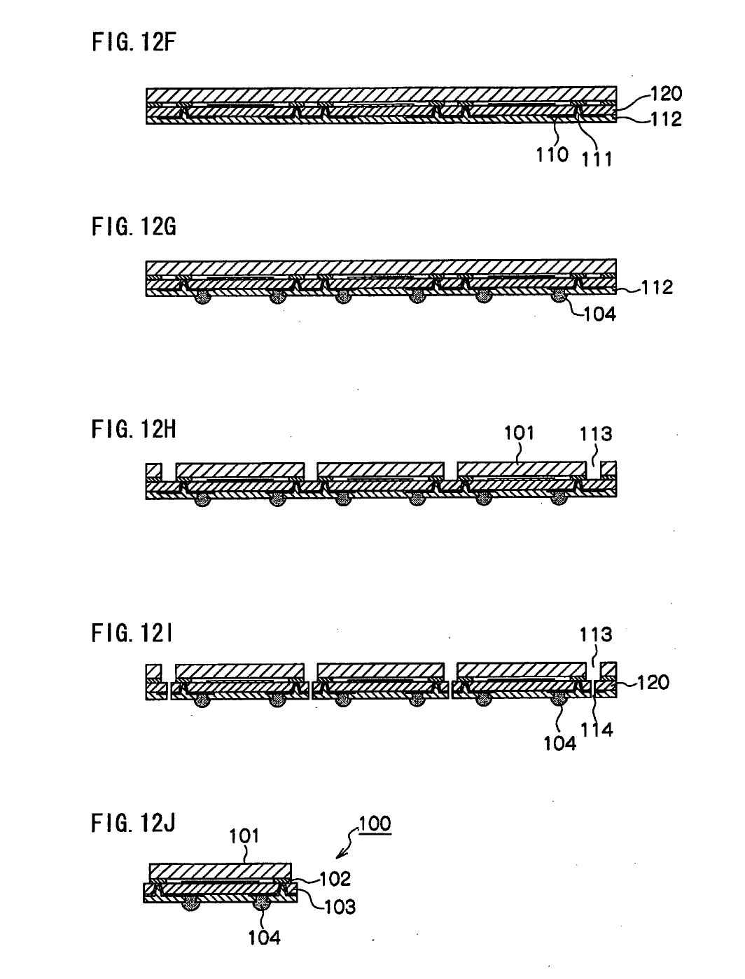

The manufacturing process of the semiconductor device 100 of the present invention illustrated in FIG. 3A will be described below with reference to FIGS. 11 and 12.

As illustrated in FIG. 11A, a semiconductor wafer 120 is prepared. The semiconductor wafer 120 has a front surface (also referred to as the element forming surface) at which the sensor element 105 and a circuit element (not illustrated) which processes an electric signal output from the controlled sensor element is formed, and a back surface located on the opposite side of the front surface. On the front surface of the semiconductor wafer 120, semiconductor element regions each including a sensor element forming region at which the sensor element 105 (e.g., an image sensor element) is formed and a circuit element forming region at which the circuit element is formed, are arrayed in a matrix in a planar view. The sensor element has a light receiving surface which receives light from the outside.

As illustrated in FIG. 11B, the adhering portion 102 is formed by avoiding the region where the sensor element 105 is located. The protective member 101 is adhered over the semiconductor wafer 120 via the adhering portion 102. The adhering portion 102 is an adhesive and is patterned by a printing, dispensing, or photolithography method. The adhering portion 102 is patterned so as not to be located in an exposed region of the semiconductor wafer 120 after the later-described dicing of the protective member 101. If the adhering portion 102 remains in the exposed region, the positioning accuracy of the holder 307 may be deteriorated when the holder 307 is mounted. Therefore, after the dicing of the protective member 101, a process for removing the remaining portion of the adhesive is necessary. In addition to the function of protecting the semiconductor element region from the outside, the protective member 101 requires the function of transmitting light received from the outside to the sensor element. For example, when the light to be received by the sensor element is visible light, the protective member 101 needs to have the function of transmitting the visible light. To selectively transmit only the visible light, coating which cuts an ultraviolet ray or an infrared ray may be provided on the surface of the protective member 101. That is, the protective member 101 may function as a filter which transmits a light having a specific wavelength required by the sensor element. As described above, the material of the protective member 101 is not limited to glass. For example, a plastic material which has the above functions may be used.

Next, as illustrated in FIG. 11C, the back surface of the semiconductor wafer 120 is ground to a predetermined thickness to make the semiconductor wafer 120 thinner.

As illustrated in FIG. 11D, the semiconductor wafer 120 is processed by a processing method using dry etching, wet etching, or laser processing so as to expose the back portion of an electrode pad (not illustrated) formed on the front surface of the semiconductor wafer 120, thereby forming a through hole 111 (hereinafter, referred to as a “through hole”, as needed). Thereafter, an insulating film (not illustrated) is formed on the side wall of the through hole 111 and the back surface of the semiconductor wafer 120.

As illustrated in FIG. 11E, a wire 110 extended from the back surface of the electrode pad onto the side wall of the through hole 111 and the back surface of the semiconductor wafer 120 is formed by sputtering or plating. The electrode pad is electrically connected to the circuit element or the sensor element by a wire (not illustrated) formed on the front surface of the semiconductor wafer. At this point, the wire 110 is electrically connected to the circuit element or the sensor element.

As illustrated in FIG. 12F, a protective film 112 such as a solder resist is formed on the wire 110 forming surface side of the semiconductor wafer 120. An opening (not illustrated) is formed in the protective film 112 located on a predetermined region of the wire 110.

As illustrated in FIG. 12G, an external terminal 104 is provided in the opening (not illustrated) formed in the protective film 112 so as to be electrically connected to the wire 110.

As illustrated in FIG. 12H, the protective member 101 is cut at a predetermined width by a dicing device to form an exposing hole 113, and a portion of the front surface of the semiconductor wafer 120 (a portion of the semiconductor element region) is exposed from the protective member 101. The predetermined width of the protective member 101 cut at this time is a first width. The cutting direction is a direction along the direction from the front toward the back in the drawing. The direction is defined as a first direction when the semiconductor wafer 120 is seen from the planar view. Although not illustrated, in the cross-section perpendicular to FIG. 12H, the protective member 101 is cut at a predetermined width and a portion of the front surface of the semiconductor wafer 120 (a portion of the semiconductor element region) is exposed from the protective member 101. The predetermined width of the protective member 101 cut at this time is a third width and the cutting direction is a direction along the direction from left to right in the drawing. This direction is defined as a second direction perpendicular to the first direction when the semiconductor wafer 120 is seen from the planar view. When the first width is larger than a later-described second width, the first width may be the same as or different from the third width.

As illustrated in FIG. 12I, the front surface of the semiconductor wafer 120 exposed in the previous process is diced at a predetermined width. The predetermined width of the semiconductor wafer 120 cut at this time is the second width, smaller than the first width. The cutting direction is the first direction.

As illustrated in FIG. 12J, the semiconductor element and the protective member 101 form individual device regions to obtain the semiconductor device 100 of the present invention. From the viewpoint of the accuracy of the dicing, it is preferred that the cutting width (the first width and the third width) of the protective member 101 is from 40 μm to 200 μm. For example, in order to make the width of the correcting-of-position surface 108 of the semiconductor device in FIG. 2B 50 μm, the first width is set to 110 μm and the second width is set to 10 μm. The correcting-of-position surface 108, after individual device regions are formed, is 50 μm.

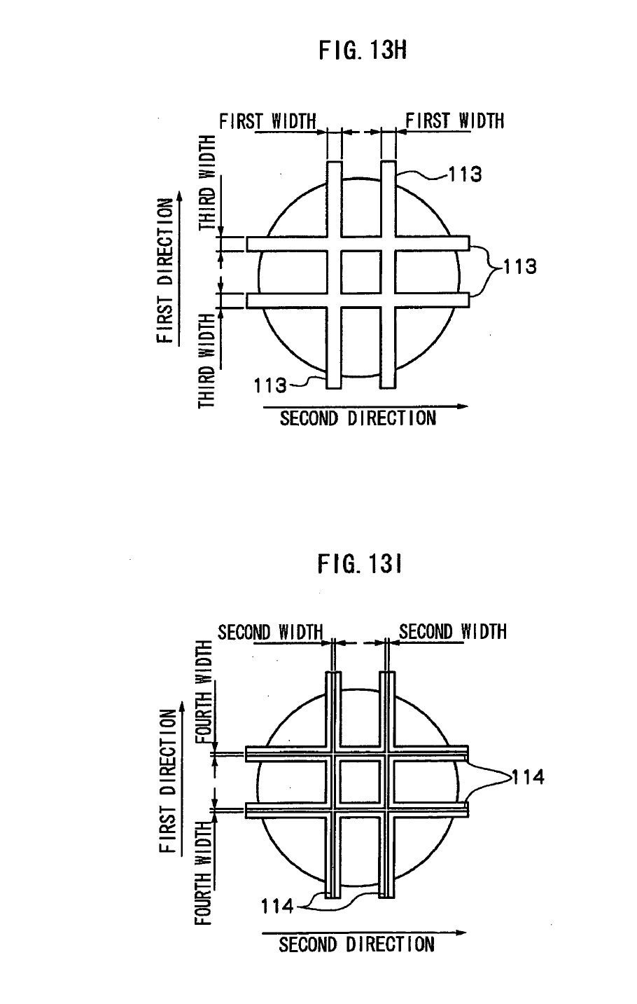

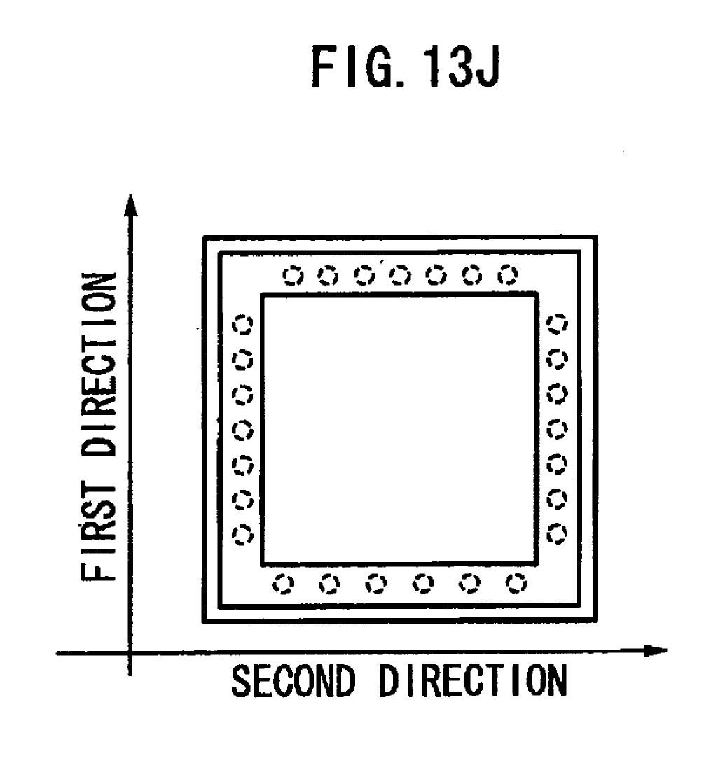

FIGS. 13H to 13J illustrate process plan views of the processes of FIGS. 12H to 12J.

As illustrated in FIG. 13H, the protecting member is diced at the first width in the first direction, and the protecting member is diced at the third width in the second direction.

As illustrated in FIG. 13I, the semiconductor element is diced at the second width smaller than the first width in the first direction, and the semiconductor element is diced at a fourth width smaller than the third width in the second direction.

As illustrated in FIG. 13J, the semiconductor element and the protecting member 101 form individual device regions to obtain the semiconductor device 100 of the invention illustrated in FIG. 3A. The dicing process is not limited to this order. For example, after the protecting member is diced at the first width in the first direction, the semiconductor element is diced at the second width smaller than the first width in the first direction. The protecting member may be diced at the third width in the second direction. The semiconductor element may be diced at the fourth width smaller than the third width in the second direction.

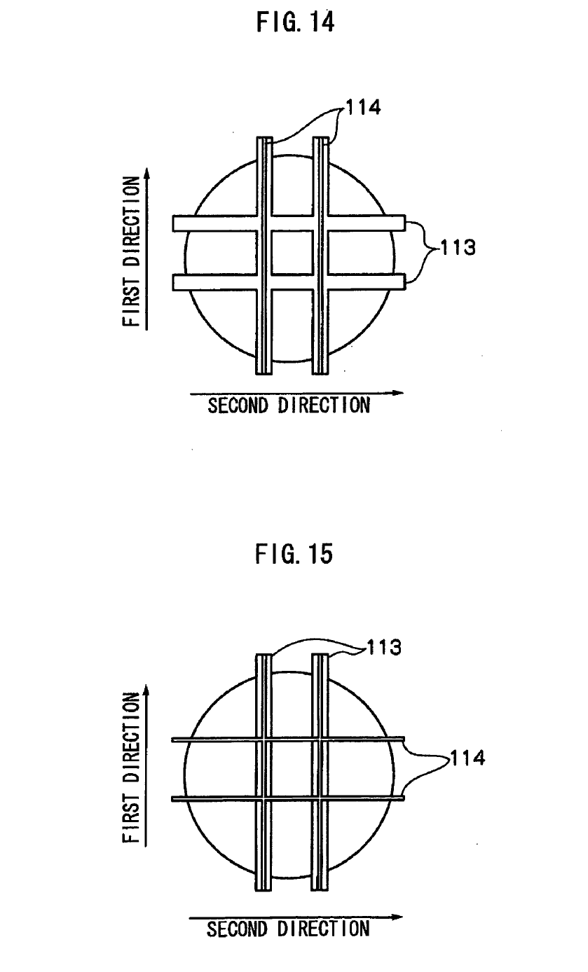

The manufacturing process of the semiconductor device of the invention illustrated in FIG. 3B will be described below along FIGS. 14 and 15.

In the manufacturing method of the semiconductor device illustrated in FIG. 3B, as illustrated in FIG. 14, the protecting member is diced at the first width in the first direction. Then, the semiconductor element and the protecting member are diced at one time at the third width in the second direction. Finally, the semiconductor element is diced at the second width smaller than the first width in the first direction. The semiconductor element and the protecting member form individual device regions to obtain the semiconductor device illustrated in FIG. 3B. The dicing order is not limited to this. For example, the protecting member is diced at the first width in the first direction. Then, the semiconductor element may be diced at the second width in the first direction. Finally, the semiconductor element and the protecting member may be diced at one time at the third width in the second direction.

As a modification of the manufacturing method of the semiconductor device illustrated in FIG. 3B, as illustrated in FIG. 15, the dicing in the second direction in FIG. 14 may be performed at the second width smaller than the first width. The semiconductor element illustrated in FIG. 3B may be obtained as in the manufacturing method of FIG. 14. In the manufacturing method of FIG. 15, as compared with the manufacturing method of FIG. 14, the dicing width is small and the number of semiconductor devices obtained from one semiconductor wafer is large. The manufacturing method of FIG. 15 is preferred in that the manufacturing efficiency is excellent.

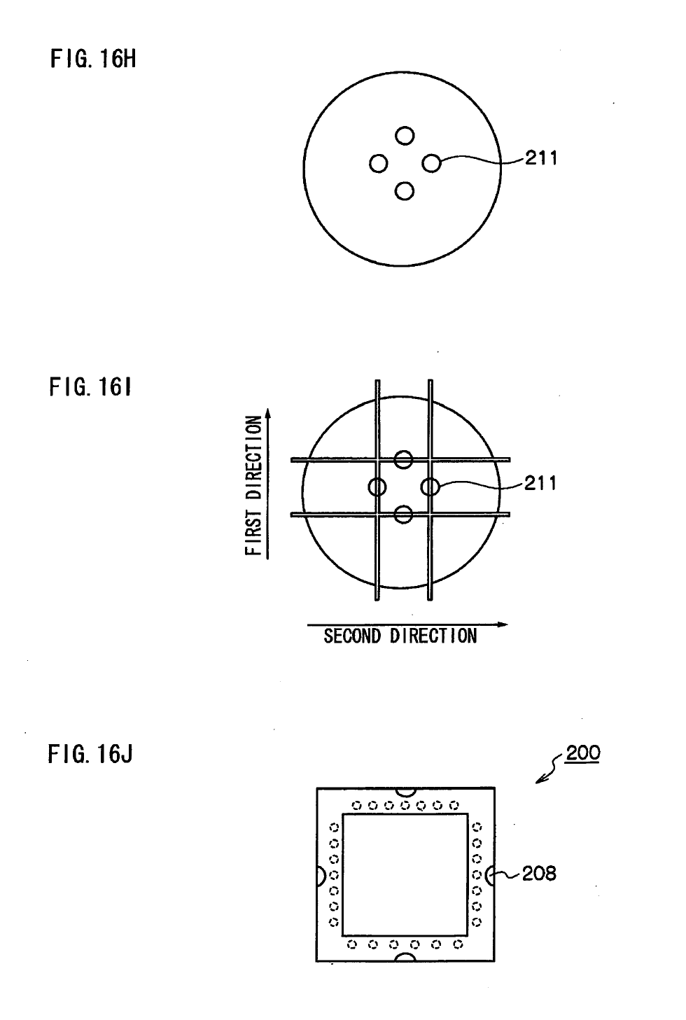

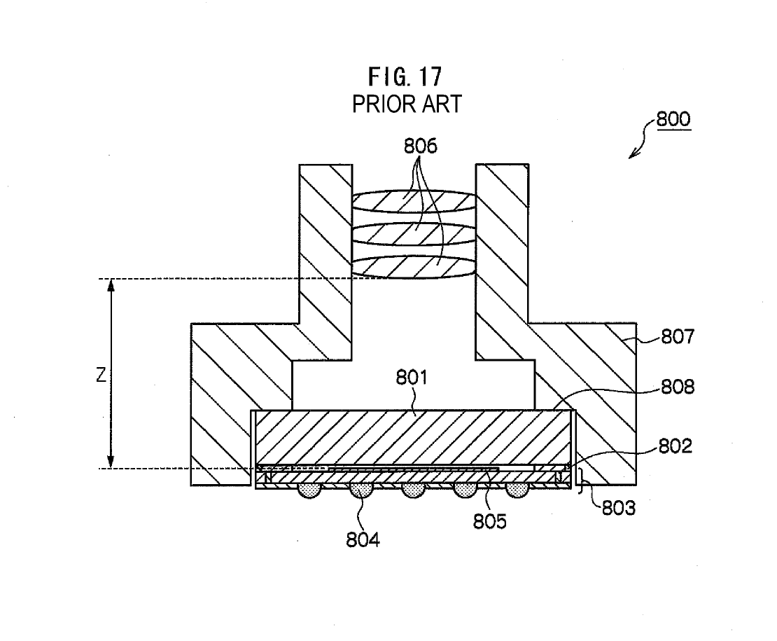

The manufacturing process of the semiconductor device 200 of the invention illustrated in FIG. 4A will be described below. In the description, FIGS. 16H to 16J illustrate process plan views which modify FIGS. 12H to 12J. The manufacturing process of the semiconductor device 200 of the invention will be described along the drawings.

As illustrated in FIG. 16H, the protecting member having the same shape as the semiconductor wafer is provided via the resin portion over the semiconductor wafer. A cylindrical exposing hole 211 is provided in the protecting member so as to expose the semiconductor element in a predetermined position to provide the correcting-of-position portion. As illustrated in FIG. 16I, the dicing is performed in the first direction and the second direction. As illustrated in FIG. 16J, the semiconductor device 200 having the correcting-of-position surface 208 may be obtained.

The dicing width may be the first width for dicing the protecting member or the second width for cutting the semiconductor element. From the viewpoint of the manufacturing efficiency in which more semiconductor devices may be obtained from one semiconductor wafer, it is preferred that the dicing be performed at the smallest possible width.

### <A Camera Module Manufacturing Method>

In a camera module manufacturing method of the invention, the semiconductor device manufactured by the semiconductor device manufacturing method is prepared, is inserted into the holder which inserts the lens therein and has a position so as to engage the correcting-of-position surface, and is fixed by any one of the engaging means.

This exemplary embodiment is not limitatively understood and may be realized in the range satisfying the requirement of the invention.

1. A semiconductor device comprising:
a semiconductor element having an element forming surface at which a sensor element is formed, and a back surface at an opposite side of the element forming surface; and
a light transmissive protective member laminated over the element forming surface via an adhering portion,
wherein when viewed from a side of the protective member, the element forming surface of the semiconductor element includes a region exposed from the protective member at an outer peripheral end portion of the semiconductor element, and
wherein the exposed region is provided partially along the outer peripheral end portions of the semiconductor element.

2. The semiconductor device of claim 1, wherein the exposed region is provided along each of at least one pair of opposing sides at the outer peripheral end portions of the semiconductor element.

3. The semiconductor device of claim 1, wherein the exposed region is provided at a portion of each of the at least one pair of opposing sides at the outer peripheral end portions of the semiconductor element, and at least three exposed regions are provided at the outer peripheral end portions of the semiconductor element.

4. The semiconductor device of claim 3, wherein the exposed region is provided at a central portion of each of the at least one pair of opposing sides at the outer peripheral end portions of the semiconductor element.

5. The semiconductor device of claim 3, wherein the exposed region is provided at a corner portion of the semiconductor element.

6. The semiconductor device of claim 1, wherein the semiconductor element comprises:
a through hole penetrating from the element forming surface to the back surface;
an external terminal provided on the back surface; and
a wiring pattern of which a portion is formed inside the through hole to electrically connect the sensor element and the external terminal.

7. A camera module comprising a lens, a holder in which the lens is inserted and which holds the lens therein, and a semiconductor device in which a protective member is laminated via an adhering portion over an element forming surface at which a semiconductor element sensor is formed,
wherein the semiconductor device is the semiconductor device of claim 1 and the holder is fixed so as to engage the exposed region on the element forming surface of the semiconductor element of the semiconductor device.

8. The camera module of claim 7, wherein the holder is fixed so as to engage the exposed region of the semiconductor device so as to cover a side surface of the semiconductor element.

9. A semiconductor device comprising:
a semiconductor element having a first main surface and a second main surface opposite to the first main surface;
a sensor element formed on the first main surface; and
a protective member formed over the first main surface and having a light transmitting property,
wherein outer peripheral end portions on the first main surface are partially exposed from the protective member, when viewed from a side of the protective member.

10. The semiconductor device of claim 9, wherein the end portions exposed from the protective member are provided along a pair of opposing sides of the semiconductor element.

11. The semiconductor device of claim 9, wherein the end portions exposed from the protective member are provided at opposing sides of the semiconductor element.

12. The semiconductor device of claim 11, wherein the end portions exposed from the protective member are provided at a center of the sides of the semiconductor element.

13. The semiconductor device of claim 11, wherein the end portions exposed from the protective member are provided at a corner of the semiconductor element.

14. The semiconductor device of claim 11, wherein the end portions exposed from the protective member are provided at three portions.

15. The semiconductor device of claim 9, wherein the semiconductor element comprises:
a through hole penetrating from the first main surface to the second main surface;
an external terminal provided on the second main surface; and
a wiring pattern extending from the through hole to the external terminal and electrically connecting the sensor element to the external terminal.

16. A semiconductor device comprising:
a semiconductor element having a first main surface and a second main surface opposite to the first main surface;
a sensor element formed on the first main surface; and
a protective member formed over the first main surface and having a light transmitting property, wherein
an outer dimension of the protective member is smaller than that of the semiconductor element so that outer peripheral end portions of the first main surface are partially exposed, when viewed from a side of the protective member.

17. The semiconductor device of claim 16, wherein the protective member has an outer edge that exposes portions of the first main surface.

18. The semiconductor device of claim 17, wherein the outer edge exposes a portion of opposing sides of the semiconductor element.

19. The semiconductor device of claim 17, wherein the outer edge exposes a corner of the semiconductor element.

20. The semiconductor device of claim 17, wherein the outer edge exposes a center of the side of the semiconductor element.
